(19) United States
(12) Patent Application Publication
(10) Pub. No.: US 2016/0013012 A1
(43) Pub. Date: Jan. 14, 2016

(54) Charged Particle Beam System

(71) Applicant: JEOL Ltd., Tokyo (JP)

(72) Inventor: Takeo Sasaki, Tokyo (JP)

(21) Appl. No.: 14/668,060

(22) Filed: Mar. 25, 2015

(30) Foreign Application Priority Data
Mar. 26, 2014 (JP) 2014-63591

(51) Int. Cl. H01J 37/04; H01J 37/10; H01J 37/26

(52) U.S. Cl. CPC H01J 37/045; H01J 37/26; H01J 37/10; H01J 2237/0435; H01J 2237/2802

(57) ABSTRACT

A charged particle beam system has a charged particle beam source (110) for producing a charged particle beam (EB), a beam blanker (1) and a sample stage (130) on which a sample (S) is held. The sample (S) is irradiated with the beam (EB) passed through the beam blanker (1). The beam blanker (1) has a multistage deflector assembly (20) and a first apertured portion (30). Multiple stages of deflectors (20a, 20b, 20c) for deflecting the beam (EB) are arranged in the multistage deflector assembly (20). The first apertured portion (30) is disposed between the first stage of deflector (20a) and the second stage of deflector (20b) of the deflector assembly (20). The beam (EB) which has passed through the first aperture portion (30) after being deflected by the first stage of deflector (20a) is deflected back to an optical axis (OA) by the second and subsequent stages of deflectors (20a, 20b).

### BACKGROUND OF THE INVENTION

1. Field of the Invention

The present invention relates to a charged particle beam system.

2. Description of Related Art

In a charged particle beam system such as a transmission electron microscope (TEM), when an electron microscope image or an electron diffraction pattern should be taken, the shutter is first activated to prevent the electron beam from hitting film or an imager such as a CCD camera. Then, the beam is made to hit the film or imager to expose it. Subsequently, the shutter is again activated such that the beam does not hit the film or imager. Consequently, the electron microscope image or electron diffraction pattern can be taken (see, for example, JPA-2006-100166).

One known shutter of this type is a shutter using gun alignment coils (hereinafter may also be referred to as a gun shutter). FIG. 7 schematically shows a transmission electron microscope, 1000, that is one example of a transmission electron microscope equipped with a gun shutter.

In the transmission electron microscope 1000, a voltage is applied to the extractor electrode 1012 of an electron gun 1010 to emit an electron beam EB from an emitter 1011. The beam passes through an acceleration tube 1014 while undergoing a focusing force from an electrostatic lens 1013. The beam then forms a first crossover near gun alignment coils 1015 and 1016. After being emitted from the electron gun 1010, the electron beam EB passes through a fixed condenser aperture 1021, is focused by a condenser lens assembly 1020 and an objective lens 1030, and impinges on a sample S held on a sample stage 1038. The beam EB transmitted through the sample S passes through the objective lens 1030, an intermediate lens 1040, and a projector lens 1050, thus producing a focused electron microscope image or electron diffraction pattern of the sample S on a fluorescent screen 1070.

Shuttering techniques used when an electron microscope image or electron diffraction pattern is recorded on photographic film or captured by a digital camera 1080 in transmission electron microscopy include two types of shuttering. One type of shuttering makes use of electromagnetic deflection using the gun alignment coils 1015 and 1016. The other type of shuttering uses a mechanical shutter 1060 present under the projector lens 1050. The shuttering using the gun alignment coils 1015 and 1016 is described below.

FIG. 8 illustrates shuttering making use of electromagnetic deflection using the gun alignment coils 1015 and 1016. When an electron microscope image of the sample S is observed on the fluorescent screen 1070 (FIG. 7), the magnitudes of the magnetic fields produced by the gun alignment coils 1015 and 1016 are so set that the electron beam EB falls on the fluorescent screen 1070. Consequently, the beam EB passes through a path A1 and through a fixed gun aperture 1017 and impinges on the fluorescent screen 1070.

On the other hand, when the beam is blanked, the magnitudes of the magnetic fields produced by the gun alignment coils 1015 and 1016 are varied such that the electron beam EB is cut off by the fixed gun aperture 1017. Consequently, the beam EB passes through a path A2 and is cut off by the fixed gun aperture 1017. Therefore, the beam EB does not fall on the fluorescent screen 1070. The shuttering using the gun alignment coils 1015 and 1016 has the advantage that the beam EB does not hit the sample S during blanking because the beam EB is blanked ahead of the sample S. The shuttering process using the gun alignment coils 1015 and 1016 is described in further detail by referring still to FIGS. 7 and 8.

If a user raises the fluorescent screen 1070, a microscope controller 1090 sends positional information indicating that the fluorescent screen 1070 has been raised to a digital camera controller 1092. In response to this information, the digital camera controller 1092 outputs a gun shutter control signal to a blanking control circuit 1094.

The blanking control circuit 1094 applies a blanking voltage to the gun alignment coils 1015 and 1016. Thus, the gun alignment coils 1015 and 1016 produce magnetic fields, deflecting the electron beam EB. The beam EB is cut off by the fixed gun aperture 1017 in the path A2 shown in FIG. 8. As a result, the beam EB does not reach the digital camera 1080.

When the user depresses a start button on a digital camera control portion 1096 for previewing or acquisition of an image, the digital camera controller 1092 outputs a gun shutter control signal at intervals corresponding to an exposure time. The blanking control circuit 1094 receives this gun shutter control signal and applies a blanking voltage to the gun alignment coils 1015 and 1016 in synchronism with the received gun shutter control signal.

During application of the blanking voltage, the electron beam EB is cut off by the fixed gun aperture 1017 located under the gun alignment coils 1015 and 1016 in the path A2 shown in FIG. 8 and so the beam EB does not reach the digital camera 1080. When the blanking voltage is not applied, the electron beam EB hits the sample S in the path A1 shown in FIG. 8. The beam EB reaches the digital camera 1080, so that the electron microscope image or electron diffraction pattern is made previewable or recorded.

When the user stops the previewing by manipulating the digital camera controller 1096 or after an image acquisition button is depressed and an image is acquired, a blanking voltage is applied to the gun alignment coils 1015 and 1016, providing a waiting condition for the next shuttering operation.

If the user lowers the fluorescent screen 1070, the gun shutter control signal delivered from the digital camera controller 1092 is ceased, and the electron beam EB is made to impinge on the fluorescent screen 1070.

During a shuttering operation using the gun alignment coils 1015 and 1016, the electron beam is blanked by the magnetic fields and, therefore, the rate at which the electron beam EB is deflected, i.e., the rate of rise and the rate of fall, is on the order of tens of microseconds. Consequently, the shuttering speed, i.e., the exposure time, can be shortened only to the order of 50 ms. It has been difficult to achieve higher shuttering speeds.

Where an electrostatic field is used to deflect the electron beam EB, faster shuttering speeds are achieved than where magnetic fields produced by the gun alignment coils 1015 and 1016 are used. Hence, shorter exposure times can be accomplished.

FIG. 9 illustrates a shuttering process using an electrostatic field generated by a deflector electrode 1110. As shown in this figure, a fixed entrance aperture 1100, the electrostatic deflector plate 1110, a fixed exit aperture 1120, and a fixed exit aperture 1130 are disposed under an electron gun (not shown). In this structure of shutter, when no blanking voltage is applied to the electrostatic deflector plate 1110, the electron beam EB passes through a path B1. When a blanking voltage is applied to the electrostatic deflector plate 1110, the beam EB passes through a path B3 and is cut off by the exit aperture 1130. The shuttering process is the same as for the process using the aforementioned gun alignment coils 1015 and 1016 except that the electron beam EB is deflected by the electrostatic deflector plate 1110.

In this shutter, during the blanking process, the angle of incidence of the electron beam EB to the sample S varies as shown in FIG. 9. In particular, when the beam EB is making a transition from the path B1 to the path B3, the beam is deflected by the electrostatic deflector plate 1110 and passes through a path B2 going through the exit aperture 1130 and so the angle of incidence to the sample S varies. Therefore, when an electron diffraction pattern is obtained, the position of the pattern shifts during a blanking process. In consequence, during photographing of the electron diffraction pattern, the pattern tails off and blurs. This presents the problem that the electron diffraction pattern cannot be photographed precisely.

### SUMMARY OF THE INVENTION

In view of the foregoing problem, the present invention has been made. One object associated with some aspects of the present invention is to provide a charged particle beam system capable of suppressing the angle of incidence of an electron beam to a sample from varying during a shuttering process.

(1) A charged particle beam system associated with the present invention has a charged particle beam source for producing a charged particle beam, a beam blanker for blanking the charged particle beam produced from the charged particle beam source, and a sample stage for holding a sample on which the charged particle beam passed through the beam blanker impinges. The beam blanker has a multistage deflector assembly having multiple stages of deflectors for deflecting the charged particle beam and a first apertured portion disposed between first and second stages of deflectors of the multistage deflector assembly. The charged particle beam which has passed through the first apertured portion after being deflected by the first stage of deflector is deflected back to an optical axis by the second and subsequent stages of deflectors of the multistage deflector assembly.

In this charged particle beam system, during a shuttering process, the angle of incidence of the charged particle beam to the sample can be suppressed from varying; otherwise, the position of the electron diffraction pattern would vary.

(2) In one feature of this charged particle beam system, there is further provided a condenser lens assembly for focusing the charged particle beam passed through the beam blanker onto the sample. The beam blanker may be disposed between the charged particle beam source and the condenser lens assembly.

In this charged particle beam system, the charged particle beam can be blanked ahead of the sample (i.e., on the upstream side relative to the direction of flow of the charged particle beam). Therefore, during blanking, the charged particle beam does not hit the sample; otherwise, the sample would be damaged.

(3) In one feature of this charged particle beam system, the beam blanker may have a lens for forming a crossover of the charged particle beam at a principal plane of deflection of the first stage of deflector.

In this charged particle beam system, during shuttering, positional deviations of the charged particle beam on the sample can be suppressed.

(4) In a further feature of this charged particle beam system, there may be further provided an imaging lens system for focusing the charged particle beam transmitted through the sample.

(5) In a further feature of this charged particle beam system, there may be further provided an objective lens including an upper polepiece and a lower polepiece which are disposed on opposite sides of the sample stage. The beam blanker may be disposed between the upper polepiece and the sample stage.

In this charged particle beam system, during a shuttering operation, the angle of incidence of the charged particle beam to the sample can be suppressed from varying; otherwise, the position of the electron diffraction pattern would vary. Furthermore, miniaturization of the beam blanker can be achieved.

(6) In an additional feature of this charged particle beam system, the multistage deflector assembly may produce electric fields to deflect the charged particle beam.

In this charged particle beam system, higher shuttering speeds can be accomplished as compared with the case where the charged particle beam is blanked, for example, by a magnetic field.

(7) In a still other feature of this charged particle beam system, the multiple stages of deflectors of the multistage deflector assembly may be three stages of deflectors. The charged particle beam is deflected through θ1, θ2, and θ3 by the first, second, and third stages, respectively, of deflectors of the deflector assembly. The angles of deflection θ1, θ2, and θ3 have the relationship: |θ1|:|θ2|:|θ3|=1:2:1. The angle of deflection θ1 and angle of deflection θ3 may be opposite in sign to the angle of deflection θ2.

In this charged particle beam system, the charged particle beam which has passed through the first apertured portion after being deflected by the first stage of deflector can be deflected back to the optical axis by the second and third stages of deflectors.

(8) In a yet other feature of this charged particle beam system, the beam blanker may further include a second apertured portion disposed between the second and third stages of deflectors of the deflector assembly.

In this charged particle beam system, only those charged particles of the charged particle beam which are close to the optical axis can be passed.

(9) In a still further feature of this charged particle beam system, there may be further provided a current measuring section for measuring the amount of current of the charged particle beam hitting the first apertured portion.

In this charged particle beam system, information about the dose of the charged particle beam hitting the sample can be obtained.

(10) In a still further feature of this charged particle beam system, the first apertured portion may include an apertured plate having plural aperture openings. The apertured plate may be movably mounted.

In this charged particle beam system, the diameters of the aperture openings can be reduced. This permits a decrease in the angle of deflection of the charged particle beam in the first stage of deflector during blanking. Consequently, higher shuttering speeds can be accomplished.

(11) In a yet other feature of this charged particle beam system, there may be further provided a current measuring section for measuring the amount of current of the charged particle beam hitting the second apertured portion.

In this charged particle beam system, information about the dose of the charged particle beam hitting the sample can be obtained.

### BRIEF DESCRIPTION OF THE DRAWINGS

FIG. 1 is a schematic vertical cross section, partly in block form, of a charged particle beam system associated with a first embodiment of the present invention.

FIG. 2 is a schematic representation of a beam blanker included in the charged particle beam system shown in FIG. 1.

FIG. 3 is a diagram illustrating the relationship between angles of deflection θ1, θ2, and θ3 of an electron beam deflected by first, second, and third stages of deflectors, respectively, of a multistage deflector assembly shown in FIG. 2.

FIG. 4 is a diagram illustrating the intensities of an electron beam on a fluorescent screen shown in FIG. 1 during shuttering.

FIG. 5 is a diagram illustrating the rate of rise and rate of fall of electron beam intensity.

FIG. 6 is a schematic representation of main portions of a charged particle beam system associated with a second embodiment of the invention.

FIG. 7 is a schematic vertical cross section, partly in block form, of a related art transmission electron microscope equipped with gun alignment coils.

FIG. 8 is a schematic representation illustrating shuttering using electromagnetic deflection using the gun alignment coils shown in FIG. 7.

FIG. 9 is a schematic representation illustrating related art shuttering using electrostatic fields employing deflector plate electrodes.

### DESCRIPTION OF THE INVENTION

The preferred embodiments of the present invention are hereinafter described in detail with reference to the drawings. It is to be understood that the embodiments provided below do not unduly restrict the scope and content of the present invention delineated by the appended claims and that not all the configurations described below are essential constituent components of the invention.

### 1. First Embodiment

### 1.1. Configuration of Charged Particle Beam System

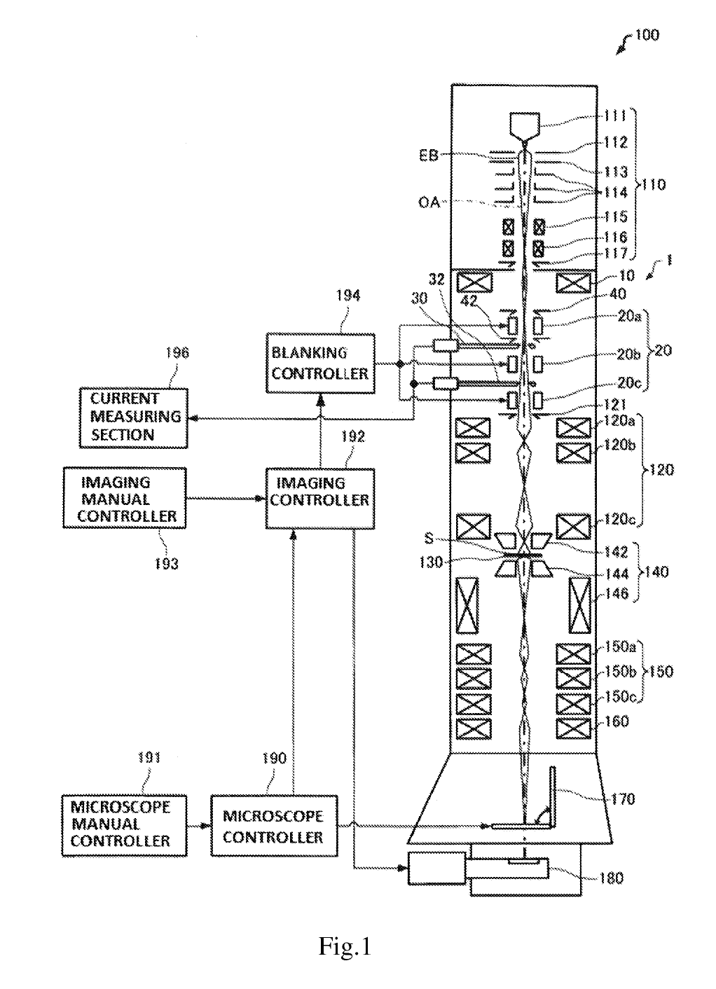

The configuration of a charged particle beam system associated with a first embodiment of the present invention is first described by referring to FIG. 1, where the system is schematically shown and generally indicated by reference numeral 100. In this example, the charged particle beam system 100 is a transmission electron microscope (TEM). A transmission electron microscope is an electron microscope for irradiating a sample S with an electron beam EB and magnifying the electron beam EB transmitted through the sample S by an imaging lens system including components 140, 150, and 160.

Referring still to FIG. 1, the charged particle beam system 100 is configured including a charged particle beam source 110, a beam blanker 1, a condenser lens system 120, a sample stage 130, the objective lens 140, the intermediate lens system 150, the projector lens 160, a fluorescent screen 170, an imager 180, a microscope controller 190, a microscope manual controller 191, an imaging controller 192, an imaging manual controller 193, a blanking controller 194, and a current measuring section 196.

The charged particle beam source 110 such as an electron beam source produces the charged particle beam EB such an electron beam. The charged particle beam source 110 is configured including an emitter 111, an extractor electrode 112, electrostatic lenses 113, an acceleration tube 114, gun alignment coils 115, 116, and a fixed gun aperture 117.

In the charged particle beam source 110, the electron beam EB is produced from the emitter 111 by a voltage applied to the extractor electrode 112. The beam EB passes through the acceleration tube 114 while undergoing a focusing force from the electrostatic lenses 113, and is emitted. The gun alignment coils 115 and 116 are used to make corrections such that the electron beam EB emitted from the charged particle beam source 110 passes through the center (optical axis OA) of the condenser lens system 120. The fixed gun aperture 117 passes only those electrons of the electron beam EB which are close to the optical axis OA, the beam EB being produced by the charged particle beam source 110. Furthermore, the fixed gun aperture 117 acts to prevent gas produced from the condenser lens system 120 from entering the charged particle beam source 110. The opening of the gun aperture 117 has a diameter of about 0.5 mm, for example. The optical axis OA is a symmetric axis passing through the center of the optical system (including the components 120, 140, 150, and 160) of the charged particle beam system 100.

A well-known electron gun can be used as the charged particle beam source 110. No restrictions are imposed on the electron gun used as the charged particle beam source 110. For example, a thermionic electron gun, a thermal field-emission electron gun, a cold field emission gun, or other electron gun can be used.

The beam blanker 1 is disposed between the charged particle beam source 110 and the condenser lens system 120 and operates to blank or cut off the electron beam EB emitted from the charged particle beam source 110. In particular, the beam blanker 1 deflects the electron beam EB emitted from the charged particle beam source 110 to cut off the beam EB. The beam blanker 1 operates as a shutter in the charged particle beam system 100.

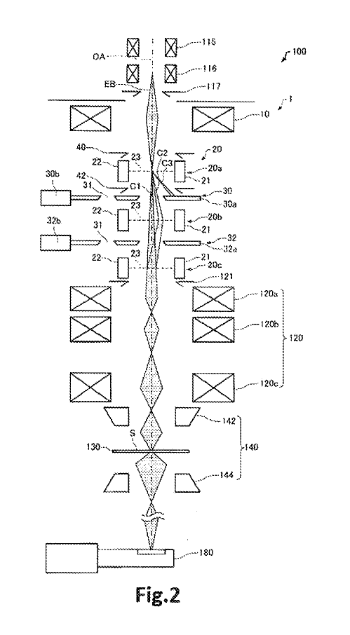

FIG. 2 shows the beam blanker 1. The beam blanker 1 is configured including an adapter lens 10, a multistage deflector assembly 20, a first apertured portion 30, a second apertured portion 32, a fixed entrance aperture 40, and a fixed exit aperture 42.

The adapter lens 10 is disposed behind the charged particle beam source 110 (i.e., on the downstream side relative to the direction of the electron beam EB). The adapter lens 10 forms a crossover of the beam EB at the principal plane of deflection 23 of the first stage of deflector (hereinafter may also be referred to as the first deflector) 20a. The principal plane of deflection 23 is a plane which is vertical to the optical axis OA of the optical system and which includes the point of intersection of the central axis of the undeflected electron beam EB (that is a central axis of the electron beam EB passing through the whole system) and the direction of the travel of the deflected electron beam EB directed toward the optical axis OA. In the illustrated example, the principal plane of deflection 23 of the first deflector 20a includes the center of the deflection plate electrodes 21 and 22 constituting the first deflector 20a and is vertical to the optical axis OA. A crossover is a position or point where the cross section of the electron beam EB is minimal when the beam EB is focused by a lens or lenses.

The multistage deflector assembly 20 is configured including plural deflectors 20a, 20b, and 20c which are arranged in multiple stages. That is, the multistage deflector assembly 20 is configured including the deflectors 20a, 20b, and 20c arranged along the optical axis OA. In the illustrated example, the first, second, and third deflectors 20a, 20b, and 20c are arranged in the first, second, and third stages, respectively. That is, the first, second, and third deflectors 20a, 20b, and 20c are arranged in this order from the upstream side relative to the direction of the electron beam EB along the optical axis OA (i.e., from the side of the charged particle beam source 110).

In the illustrated example, the multistage deflector assembly 20 has the three stages of deflectors 20a, 20b, and 20c. No restrictions are imposed on the number of stages of the multistage deflector assembly 20 as long as it has three or more stages of deflectors.

The deflectors 20a, 20b, and 20c produce static electric fields to deflect the electron beam EB. Each of the deflectors 20a-20c has two deflection plate electrodes 21 and 22 which are opposite to each other. The deflection plate electrodes 21 and 22 are arranged symmetrically with respect to the optical axis OA. A blanking voltage is applied from the blanking controller 194 to the deflection plate electrodes 21 and 22 as shown in FIG. 1. As a result, an electric field is set up between the deflection plate electrodes 21 and 22, thus deflecting the electron beam EB.

The first apertured portion 30 is disposed between the first deflector 20a and the second deflector 20b and used to cut off the electron beam EB deflected by the first deflector 20a. The first apertured portion 30 cuts off those electrons of the beam EB which are deflected through more than a given angle of deflection by the first deflector 20a. Those electrons of the beam EB which are not deflected by the first deflector 20a and those electrons of the beam EB which are deflected through less than the given angle of deflection by the first deflector 20a pass through the first apertured portion 30.

The first apertured portion 30 has an apertured plate 30a having plural (two, in the illustrated example) aperture openings 31. No restriction is placed on the number of the aperture openings 31. The number may also be singular. The diameter of the aperture openings 31 of the first apertured portion 30 is, for example, between approximately 10 μm and 200 μm, inclusively.

The apertured plate 30a is movably mounted. In the illustrated example, there is provided a driving portion 30b for moving the apertured plate 30a. The apertured plate 30a can be moved by operating the driving portion 30b. The apertured plate 30a can move, for example, through a plane perpendicular to the optical axis OA. The apertured plate 30a may be moved manually. The aperture openings 31 can be positionally adjusted by moving the apertured plate 30a in this way.

The active aperture opening 31 in the first apertured portion 30 can be switched, for example, by moving the apertured plate 30a. The first apertured plate 30 is a movable aperture having aperture openings whose diameters can be switched from outside vacuum and whose positions can be adjusted. Alternatively, the first apertured portion 30 may be a fixed aperture.

The driving portion 30b moves the apertured plate 30a on the basis of a control signal from the microscope controller 190 to switch the active aperture opening 31 and adjust its position. The first apertured portion 30 can have a function of measuring electrical currents. As shown in FIG. 1, the amount of current of the electron beam EB impinging on the first apertured portion 30 (apertured plate 30a) is measured by the current measuring section 196.

The second apertured portion 32 is disposed between the second deflector 20b and the third deflector 20c. The second apertured portion 32 can pass only those electrons of the electron beam EB which are close to the optical axis OA. The second apertured portion 32 has an apertured plate 32a having plural (two, in the illustrated example) aperture openings 31. No restriction is imposed on the number of the aperture openings 31. The number may be singular. The diameters of the aperture openings 31 of the second apertured portion 32 are, for example, between approximately 10 μm and 200 inclusively.

The apertured plate 32a is movably mounted. In the illustrated example, there is provided a driving portion 32b for moving the apertured plate 32a. The apertured plate 32a can be moved by operating the driving portion 32b. The apertured plate 32a can move, for example, through a plane perpendicular to the optical axis OA. The apertured plate 32a may be moved manually. The aperture openings 31 can be positionally adjusted by moving the apertured plate 32a in this way.

The active aperture opening 31 in the second apertured portion 32 can be switched, for example, by moving the apertured plate 32a. The second apertured portion 32 is a movable aperture having aperture openings whose diameters can be switched from outside vacuum and whose positions can be adjusted. Alternatively, the second apertured portion 32 may be a fixed aperture.

The driving portion 32b moves the apertured plate 32a on the basis of a control signal from the microscope controller 190 to switch the active aperture opening 31 and adjust its position. The second apertured portion 32 can have a function of measuring electrical currents. The amount of current of the electron beam EB impinging on the second apertured portion 32 (apertured plate 32a) is measured by the current measuring section 196. In the charged particle beam system 100, the second apertured portion 32 may be omitted.

The fixed entrance aperture 40 is arranged between the adapter lens 10 and the first deflector 20a. The fixed exit aperture 42 is located between the first deflector 20a and the first apertured portion 30. Each of the fixed entrance aperture 40 and fixed exit aperture 42 is a fixed aperture having an opening whose diameter and position are fixed. These fixed apertures 40 and 42 pass only those electrons of the electron beam EB which are close to the optical axis OA.

In the beam blanker 1, the adapter lens 10 forms a crossover of the electron beam EB at the principal plane of deflection 23 of the first deflector 20a in the first stage. The first deflector 20a deflects the beam EB to blank or cut off it by the first apertured portion 30. In this blanking process, when the electron beam EB is making a transition from a path C1 taken prior to the blanking to a path C3 in which the beam is cut off by the first apertured portion 30, the beam is deflected by the first deflector 20a and passes through a path C2 going through the first apertured portion 30.

At this time, in the multistage deflector assembly 20, the electron beam EB which has passed through the first apertured portion 30 in the path C2 after being deflected by the first deflector 20a can be deflected back to the optical axis OA by the second deflector 20b and third deflector 20c. That is, the electron beam EB which has passed through the first apertured portion 30 after being deflected by the first deflector 20a in the first stage can be deflected back to the optical axis OA by the second and following stages of deflectors 20b and 20c of the multistage deflector assembly 20. Consequently, during the blanking process where the path taken by the electron beam EB varies from the path C1 to the path C3 via the path C2, the angle of incidence to the sample S does not vary.

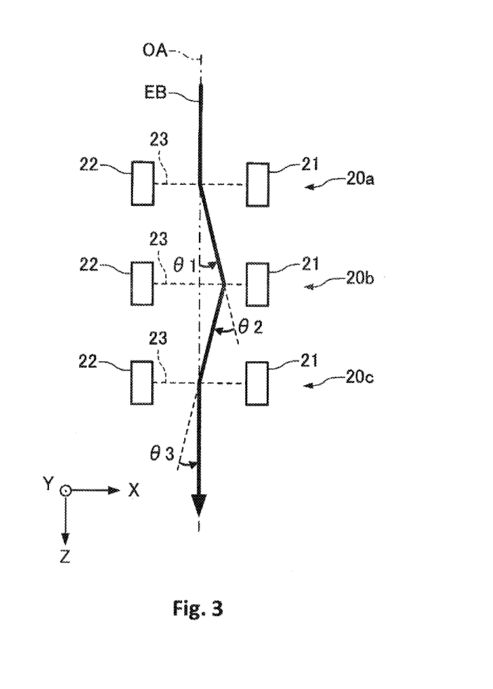

FIG. 3 is a diagram illustrating the relation between the angle of deflection θ1 of the electron beam EB in the first deflector 20a, the angle of deflection θ2 in the beam EB in the second deflector 20b, and the angle of deflection θ3 of the beam EB in the third deflector 20c. In FIG. 3, X-, Y-, and Z-axes are shown as mutually perpendicular axes. The Z-axis is parallel to the optical axis OA.

As shown in FIG. 3, the first deflector 20a deflects the electron beam EB in the positive direction of the X-axis. This deflected beam EB is deflected by the second deflector 20b in the opposite direction, i.e., in the negative direction of the X-axis. The beam EB deflected by the second deflector 20b is deflected by the third deflector 20c in the positive direction of the X-axis. Consequently, the beam EB deflected by the first deflector 20a can be returned to the optical axis OA.

More specifically, the absolute value |θ1| of the angle of deflection θ1 of the electron beam EB in the first deflector 20a, the absolute value |θ2| of the angle of deflection θ2 of the beam EB in the second deflector 20b, and the absolute value |θ3| of the angle of deflection θ3 of the beam EB in the third deflector 20c have the relationship: |θ1|: |θ2|: |θ3|=1:2:1. The angle of deflection θ1 and angle of deflection θ3 are opposite in sign to the angle of deflection θ2. That is, where the angle of deflection θ1 and angle of deflection θ3 are positive, the angle of deflection θ2 is negative. Each sign indicates the direction of the angle of deflection. Where the sign is opposite, the direction of polarization is opposite.

The blanking controller 194 applies a blanking voltage to the deflection plate electrodes 21 and 22 of the deflectors 20a, 20b, and 20c to satisfy this relationship. Consequently, the electron beam EB deflected by the first deflector 20a can be deflected back to the optical axis OA by the second deflector 20b and third deflector 20c.

In the example of FIG. 3, the deflection plate electrodes 21 and 22 constituting the deflectors 20a, 20b, and 20c are equal in length taken along the Z-axis. Furthermore, the deflecting plate electrodes 21 and 22 constituting the deflectors 20a, 20b, and 20c are equal in width, i.e., dimension taken along the Y-axis. The distance between the deflection plate electrodes 21 and 22 is uniform for all of the deflectors 20a, 20b, and 20c.

The distance between each of the deflection plate electrodes 21 and 22 of the first deflector 20a and a respective one of the deflection plate electrodes 21 and 22 of the second deflector 20b is equal to the distance between each of the deflection plate electrodes 21 and 22 of the second deflector 20b and a respective one of the deflection plate electrodes 21 and 22 of the third deflector 20c. That is, the distance between the principal plane of deflection 23 of the first deflector 20a and the principal plane of deflection 23 of the second deflector 20b is equal to the distance between the principal plane of deflection 23 of the second deflector 20b and the principal plane of deflection 23 of the third deflector 20c.

No restrictions are imposed on the conditions for the deflectors 20a, 20b, and 20c as long as the electron beam EB can be deflected back to the optical axis OA by the second and following stages of deflectors 20b and 20c. That is, the relationship between the angles of deflections θ1, θ2, and θ3 in the deflectors 20a, 20b, and 20c is not restricted to the above-described relationship. Furthermore, the lengths of the deflection plate electrodes 21 and 22 in the deflectors 20a, 20b, and 20c and the distance between the deflection plate electrodes 21 and 22 may be different among the deflectors 20a, 20b, and 20c. In addition, the distance between the principal plane of deflection 23 of the first deflector 20a and the principal plane of deflection 23 of the second deflector 20b may be different from the distance between the principal plane of deflection 23 of the second deflector 20b and the principal plane of deflection 23 of the third deflector 20c.

The condenser lens system 120 is disposed behind the beam blanker 1 as shown in FIGS. 1 and 2. After the electron beam EB is emitted from the charged particle beam source 110 and passes through the beam blanker 1, the beam is focused by the condenser lens system 120.

In the illustrated example, the condenser lens system 120 is configured including a first condenser lens 120a, a second condenser lens 120b, and a condenser minilens 120c. The first condenser lens 120a demagnifies the crossover of the electron beam EB emitted from the charged particle beam source 110. The image of the beam EB demagnified by the first condenser lens 120a is transferred to the object plane of the objective lens 140 by the second condenser lens 120b. The condenser minilens 120c creates an angle of convergence adapted, for example, for the imaging mode. A fixed condenser aperture 121 is disposed between the beam blanker 1 and the condenser lens system 120 and operates to pass only those electrons of the electron beam EB which are close to the optical axis OA.

The sample stage 130 holds the sample S. The sample stage 130 can horizontally move, vertically move, rotate, tilt, and otherwise drive the sample S. The sample stage 130 may be a side entry stage for inserting a sample holder (not shown) from a side of the objective lens 140. Alternatively, the sample stage 130 may be a top-loading stage for inserting the sample S from above the polepieces of the objective lens 140.

The objective lens 140 is disposed behind the condenser lens system 120, and is an initial stage of lens for imaging the electron beam EB transmitted through the sample S. The objective lens 140 has an upper polepiece 142, a lower polepiece 144, and a coil 146 (see FIG. 1) for producing a magnetic field between the upper polepiece 142 and the lower polepiece 144 to focus the beam EB. The upper polepiece 142 and the lower polepiece 144 are disposed on opposite sides of the sample stage 130. That is, the sample S is placed between the upper polepiece 142 and the lower polepiece 144.

The intermediate lens system 150 is disposed behind the objective lens 140 and operates to focus and magnify an electron microscope image or electron diffraction pattern formed by the objective lens 140 and to form an electron microscope image or electron diffraction pattern at the object plane of the projector lens 160.

In the illustrated example, the intermediate lens system 150 is made up of three stages of lenses. The first stage of intermediate lens, 150a, is used principally for focusing purposes. It is possible to make a switch between an electron microscope image and an electron diffraction pattern by varying the focus of the first intermediate lens 150a. In particular, where an electron microscope image is taken, the object plane of the first intermediate lens 150a and the image plane of the objective lens 140 are brought into coincidence. Where an electron diffraction pattern is taken, the object plane of the first intermediate lens 150a is brought into coincidence with the back focal plane of the objective lens 140.

The second stage of intermediate lens, 150b, is used principally to magnify an electron microscope image or electron diffraction pattern. The third stage of intermediate lens, 150c, is used chiefly to create an image that is not rotated even if the magnification is varied. Depending on magnification, an unrotated image may be created by the second intermediate lens 150b, and the electron microscope image or electron diffraction pattern may be magnified by the third intermediate lens 150c.

The projector lens 160 is disposed behind the intermediate lens system 150 and operates to further magnify the electron microscope image or diffraction pattern magnified by the intermediate lens system 150 and to focus the image or pattern onto the fluorescent screen 170 or onto the imager 180.

In the charged particle beam system 100, an imaging lens system for focusing the electron beam EB transmitted through the sample S is constituted by the objective lens 140, the intermediate lens system 150, and the projector lens 160. A mechanical shutter (not shown) may be mounted between the projector lens 160 and the fluorescent screen 170.

The fluorescent screen 170 is a member for visualizing the electron microscope image or electron diffraction pattern. The fluorescent screen 170 is applied with a fluorescent substance which is excited when bombarded with electrons. This gives rise to visible light, creating bright and dark portions of image or pattern corresponding to the intensities of electrons. When the fluorescent screen 170 is raised, the electron beam EB reaches the imager 180.

The imager 180 captures the electron microscope image or electron diffraction pattern focused by the projector lens 160. For instance, the imager 180 is a digital camera. The imager 180 outputs information about the captured electron microscope image or electron diffraction pattern. The information outputted by the imager 180 about the electron microscope image or electron diffraction pattern is processed by an image processor (not shown) and displayed on a display device (not shown). The display device is a CRT, LCD, touch panel display, or the like.

The microscope controller 190 controls the optical system (including the components 120, 140, 150, 160), the sample stage 130, the fluorescent screen 170, and other components. The microscope controller 190 receives a manual control signal from the microscope manual controller 191 and controls the optical system (including the components 120, 140, 150, 160), the sample stage 130, the fluorescent screen 170, and other components. The functions of the microscope controller 190 can be realized by hardware such as various types of processors (e.g., a CPU or DSP), various kinds of integrated circuits (e.g., IC or ASIC), or computer software.

The microscope manual controller 191 operates to obtain a manual control signal responsive to a user's manipulation or action and to send the signal to the microscope controller 190. The microscope manual controller 191 is made of buttons, keys, a touch panel display, a microphone, a track ball, a mouse, a keyboard, or the like.

When a manual control signal for raising the fluorescent screen 170 is sent from the microscope manual controller 191 to the microscope controller 190, the microscope controller 190 sends a fluorescent screen control signal to a mechanical drive (not shown) for the fluorescent screen 170. The mechanical drive receives the fluorescent screen control signal and raises the fluorescent screen 170. At this time, the microscope controller 190 sends fluorescent screen position information indicating that the fluorescent screen 170 has been raised to the imaging controller 192.

The imaging controller 192 controls the imager 180 and beam blanker 1 to capture an electron microscope image or diffraction pattern. The functions of the imaging controller 192 can be realized by hardware such as various kinds of processors (e.g., a CPU or DSP) or various kinds of integrated circuits (e.g., IC or ASIC) or by computer software.

The imaging manual controller 193 operates to obtain a manual control signal responsive to a user's manipulation or action and to send the signal to the imaging controller 192. The imaging manual controller 193 has buttons for previewing electron microscope images and electron diffraction patterns and buttons for recording electron microscope images and electron diffraction patterns. The imaging manual controller 193 permits the user to set an exposure time. The imaging manual controller 193 is made of buttons, keys, a touch panel display, a microphone, a mouse, a keyboard, or the like.

When the fluorescent screen position information indicating that the fluorescent screen 170 has been raised is inputted to the imaging controller 192, the controller 192 sends a blanking control signal to the blanking controller 194. Consequently, a blanking voltage is applied to the deflectors 20a, 20b, and 20c of the beam blanker 1 from the blanking controller 194, thus blanking the electron beam EB.

During blanking of the electron beam EB, if a manual control signal for image capture is sent from the imaging manual controller 193 to the imaging controller 192, the imaging controller 192 outputs a blanking control signal at intervals corresponding to the set exposure time.

In response to the blanking control signal from the imaging controller 192, the blanking controller 194 applies a blanking voltage to the deflection plate electrodes 21 and 22 of the deflectors 20a, 20b, and 20c. The functions of the blanking controller 194 can be realized by hardware such as various kinds of processors (e.g., a CPU or DSP) or various kinds of integrated circuits (e.g., IC or ASIC) or by computer software.

The blanking controller 194 applies the blanking voltage to the deflection plate electrodes 21 and 22 of the deflectors 20a, 20b, and 20c at intervals synchronized with the received blanking control signal. As a consequence, an electron microscope image or electron diffraction pattern can be obtained in the set exposure time.

The current measuring section 196 measures the amount of current of the electron beam EB impinging on at least one of the first apertured portion 30 and second apertured portion 32. The current measuring section 196 measures the dose of the beam EB impinging on the apertured portions 30 and 32 (apertured plates 30a and 32a) as the amount of current. The current measuring section 196 provides control to display the results of the measurement, for example, on the display device (not shown).

### 1.2. Operation of Charged Particle Beam System

The operation of the charged particle beam system 100 is next described by referring to FIGS. 1 and 2. An example in which an electron microscope image is taken by the charged particle beam system 100 is given.

In the charged particle beam system 100, the electron beam EB is emitted from the emitter 111 by a voltage applied to the extractor electrode 112, and the beam EB passes through the acceleration tube 114 while undergoing a focusing force from the electrostatic lenses 113. The beam EB forms a crossover near the gun alignment coils 115 and 116.

After being emitted from the charged particle beam source 110, the electron beam EB enters the beam blanker 1, where the beam EB is made to form a crossover at the principal plane of deflection 23 of the first deflector 20a by the adapter lens 10. Since no blanking voltage is applied to the deflectors 20a, 20b, and 20c of the beam blanker 1 at this time, the beam EB travels in the path C1 (FIG. 2) and passes through the beam blanker 1.

The electron beam EB transmitted through the beam blanker 1 passes through the fixed condenser aperture 121, is focused by the condenser lens system 120 and objective lens 140, and hits the sample S held on the sample stage 130.

The electron beam EB transmitted through the sample S undergoes a lens action from the objective lens 140, intermediate lens system 150, and projector lens 160. The fluorescent screen 170 is in a closed state. An electron microscope image is focused onto the fluorescent screen 170.

When the user manipulates the microscope manual controller 191 and a manual control signal for raising the fluorescent screen 170 is sent to the microscope controller 190, the microscope controller 190 sends a fluorescent screen control signal to the mechanical drive (not shown) for the fluorescent screen 170. In response to the fluorescent screen control signal, the mechanical drive raises the fluorescent screen 170. At this time, the microscope controller 190 sends fluorescent screen position information indicating that the fluorescent screen 170 has been raised to the imaging controller 192.

In response to the fluorescent screen position information indicating that the fluorescent screen 170 has been raised, the imaging controller 192 sends a blanking control signal to the blanking controller 194. In response to the blanking control signal, the blanking controller 194 applies a blanking voltage to the deflectors 20a, 20b, and 20c of the beam blanker 1. Consequently, the electron beam EB passes through the path C3 (FIG. 2) and is blanked or cut off in the first apertured portion 30.

As a result, the electron beam EB neither hits the sample S nor reaches the imager 180. Thus, preparations for a shuttering process are complete. In the shuttering process, the state of the beam EB is switched between an unblanked state in which the electron beam EB is unblanked and a blanked state in which the beam EB is blanked (i.e., cut off).

If the user depresses a button on the imaging manual controller 193 for taking an electron microscope image, the imaging manual controller 193 sends a manual control signal for this image capture to the imaging controller 192. In response to this manual control signal, the imaging controller 192 outputs a blanking control signal at intervals corresponding to the set exposure time. The blanking controller 194 applies a blanking voltage to the deflection plate electrodes 21 and 22 of the deflectors 20a, 20b, and 20c at time intervals corresponding to the received blanking control signal.

When the blanking voltage is applied to the deflectors 20a, 20b, and 20c, the electron beam EB is blocked by the first apertured portion 30 and does not reach the imager 180. When no blanking signal is applied to the deflectors 20a, 20b, and 20c, the beam EB reaches the imager 180 and an electron microscope image is taken.

In this way, in the charged particle beam system 100, the state of the beam EB is switched by the beam blanker 1 between an unblanked state in which the electron beam EB passes through the path C1 and a blanked state in which the beam EB passes through the path C3 and is blanked. That is, shuttering of the beam is affected.

In a shuttering process, the electron beam EB which has passed through the first apertured portion 30 in the path C2 after being deflected by the first deflector 20a can be deflected back to the optical axis OA by the second deflector 20b and third deflector 20c of the beam blanker 1. Therefore, the angle of incidence of the electron beam EB to the sample S can be suppressed from varying by the beam blanker 1 when the state of the beam is switched between an unblanked state in which the electron beam EB is unblanked and a blanked state in which the beam EB is blanked.

When the imager 180 captures an electron microscope image, the imaging controller 192 sends a blanking control signal to the blanking controller 194, which in turn applies a blanking voltage to the deflection plate electrodes 21 and 22 of the deflectors 20a, 20b, and 20c. Consequently, the electron beam EB is blanked, and the charged particle beam system enters a waiting state.

If the user manipulates the microscope manual controller 191 and a control signal for lowering the fluorescent screen 170 is sent to the microscope controller 190, then the controller 190 sends a fluorescent screen control signal to the mechanical drive (not shown) for the fluorescent screen 170. In response to the fluorescent screen control signal, the mechanical drive lowers the fluorescent screen 170. At this time, the microscope controller 190 sends fluorescent screen position information indicating that the fluorescent screen 170 has been lowered to the imaging controller 192.

In response to the fluorescent screen position information indicating that the fluorescent screen 170 has been lowered, the imaging controller 192 ceases outputting the blanking control signal. Consequently, the blanking controller 194 ceases the application of the blanking voltage, and the electron beam EB is made to impinge on the fluorescent screen 170.

A case in which an electron microscope image is taken by the charged particle beam system 100 has been described. Where an electron diffraction pattern is taken by the charged particle beam system 100, the system operates similarly except that the focal distance of the first intermediate lens 150a is varied and a description thereof is omitted.

The charged particle beam system 100 has the following features. In the charged particle beam system 100, the beam blanker 1 includes the multistage deflector assembly 20 having the multiple stages of deflectors 20a, 20b, and 20c for deflecting the electron beam EB and the first apertured portion 30 disposed between the first deflector 20a in the first stage and the second deflector 20b in the second stage of the multistage deflector assembly 20. The electron beam EB which has passed through the first apertured portion 30 after being deflected by the first deflector 20a in the first stage is deflected back to the optical axis OA by the second and following stages of deflectors 20b and 20c of the multistage deflector assembly 20. Consequently, during shuttering, it is possible to suppress the angle of incidence of the electron beam EB to the sample S from varying; otherwise, the position of the electron diffraction pattern would vary.

In the charged particle system 100, the beam blanker 1 is located between the charged particle beam source 110 and the condenser lens system 120. This makes it possible to blank the electron beam EB ahead of the sample S, i.e., on the upstream side relative to the flow of the beam EB. Therefore, during the blanking, the beam EB does not hit the sample S; otherwise, the sample S would be damaged.

In the charged particle beam system 100, the beam blanker 1 has the adapter lens 10 for forming a crossover of the electron beam EB at the principal plane of deflection 23 of the first stage of deflector 20a. This can suppress positional deviations of the beam EB on the sample S during shuttering.

In the charged particle beam system 100, the deflectors 20a, 20b, and 20 produce electric fields to deflect the electron beam EB. Thus, shuttering can be effected at higher speeds than where the electron beam EB is blanked using a magnetic field. The beam EB can be shuttered at intervals, for example, on the order of microseconds by blanking the beam EB using electrostatic fields.

In this way, in the charged particle beam system 100, shuttering can be effected at high speed and so an electron microscope image or electron diffraction pattern can be taken in a short exposure time. Accordingly, when an in-situ observation is made, for example, under heating, under application of a tensile force, or in a gaseous environment, dynamic processes such as tissue changes, morphological variations of a specimen, and chemical reactions can be observed in greater detail. In particular, tissue changes of a specimen occurring, for example, when the specimen is being heated can be recorded at shorter intervals of time. Furthermore, where a specimen is pulled, the moment when a crack or break occurs in the specimen can be recorded. In addition, where catalyst particles are grown, for example, under a gaseous environment, the process of the growth can be recorded at shorter intervals of time.

Furthermore, in the charged particle beam system 100, during blanking, positional deviations of electron diffraction patterns are suppressed as described previously. The patterns can be taken in shorter exposure times. Consequently, an electron diffraction pattern of high intensity can be recorded without blur.

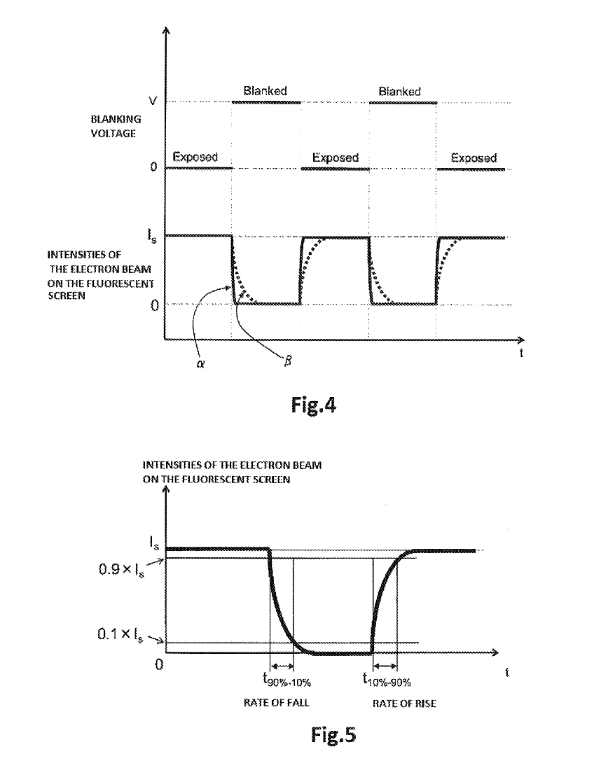

FIG. 4 shows the intensities of the electron beam EB on the fluorescent screen 170 during shuttering. Intensity α shown in FIG. 4 indicates an electron beam intensity when the electron beam EB is deflected using an electrostatic field, i.e., when an electrostatic shutter is used. Intensity β shown in FIG. 4 indicates an electron beam intensity when the beam EB is deflected by a magnetic field, i.e., when a magnetic shutter is used.

Where a magnetic shutter is used, response speeds, i.e., the rate of fall and the rate of rise, are low as shown in FIG. 4. The rate of rise is herein defined to be the response speed, t_{10%-90%}, assumed when the electron beam intensity on the fluorescent screen 170 varies from 10% to 90% when the beam EB makes a transition from a blanked state to an unblanked state for imaging as shown in FIG. 5. The rate of fall is herein defined to be the response speed, t_{90%-10%}, assumed when the electron beam intensity on the fluorescent screen 170 varies from 90% to 10% when the beam EB makes a transition from an unblanked state to a blanked state.

An electrostatic shutter provides higher rate of fall and higher rate of rise than where a magnetic shutter is used as shown in FIG. 4. Consequently, an electron microscope image or electron diffraction pattern can be obtained in a shorter exposure time.

In the charged particle beam system 100, the multistage deflector assembly 20 has the three stages of deflectors 20a, 20b, and 20c. The angle of deflection θ1 of the electron beam EB in the first stage of deflector 20a, the angle of deflection θ2 of the beam EB in the second stage of deflector 20b, and the angle of deflection θ3 of the beam EB in the third stage of deflector 20c have the relationship: |θ1|:|θ2|:|θ3|=1:2:1. The angle of deflection θ1 and angle of deflection θ3 are opposite in sign to the angle of deflection θ2. Consequently, the electron beam EB which has passed through the first apertured portion 30 after being deflected by the first stage of deflector 20a can be deflected back to the optical axis OA by the second deflector 20b and the third deflector 20c.

In the charged particle beam system 100, the beam blanker 1 has the second apertured portion 32 positioned between the second stage of deflector 20b and the third stage of deflector 20c. Hence, only those electrons of the electron beam EB which are close to the optical axis OA can be passed.

Furthermore, in the charged particle beam system 100, the current measuring section 196 measures the amount of current of the electron beam EB impinging on the first apertured portion 30. In consequence, information about the dose of the beam EB hitting the sample S can be obtained.

Additionally, in the charged particle beam system 100, the current measuring section 196 measures the amount of current of the electron beam EB impinging on the second apertured portion 32. In consequence, information about the dose of the beam EB hitting the sample S can be obtained.

Further, in the charged particle beam system 100, the first apertured portion 30 has the apertured plate 30a provided with the plural aperture openings 31. The apertured plate 30a is movably mounted. That is, the first apertured portion 30 permits switching and positional adjustment of the active aperture opening. Therefore, the first apertured portions 30 can have smaller aperture opening diameters as compared with the case where the first apertured portion 30 is a fixed aperture. This permits the angle of deflection of the electron beam EB in the first deflector 20a assumed during blanking to be reduced. That is, the blanking voltages applied to the deflectors 20a, 20b, and 20c can be reduced. Consequently, shuttering can be effected at higher speeds.

### 2. Second Embodiment

### 2.1. Configuration of Charged Particle Beam System

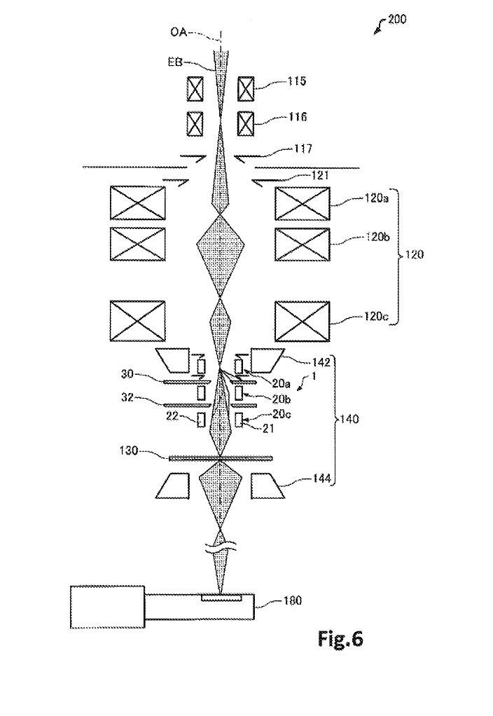

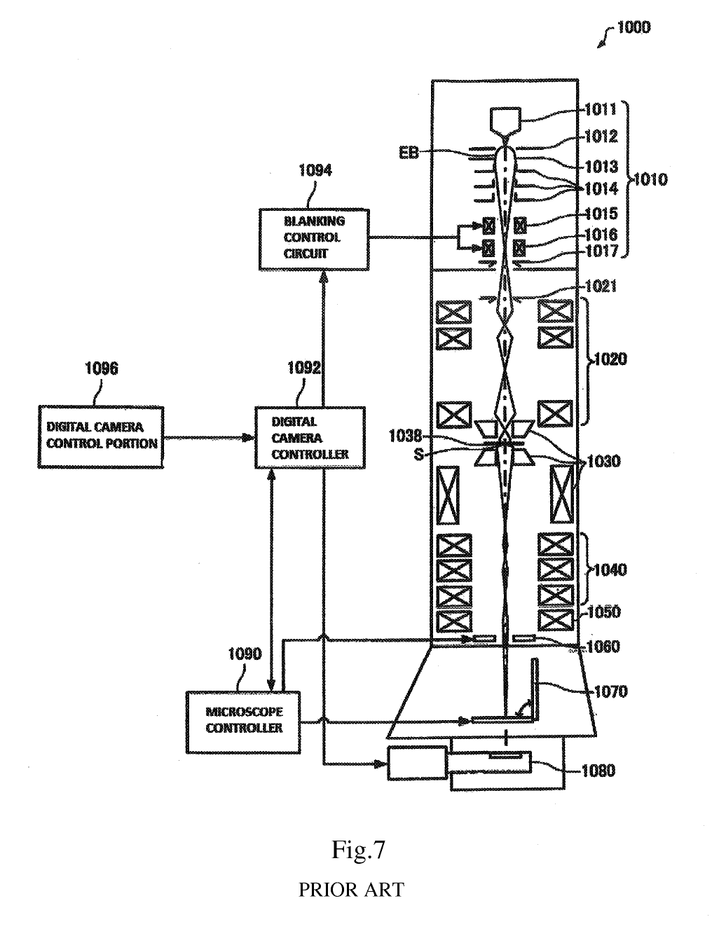

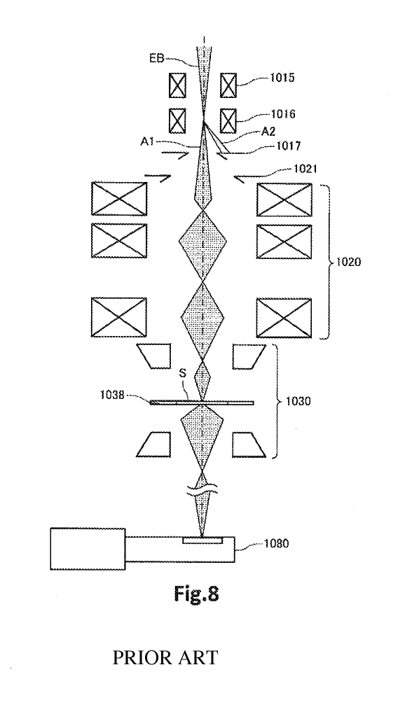

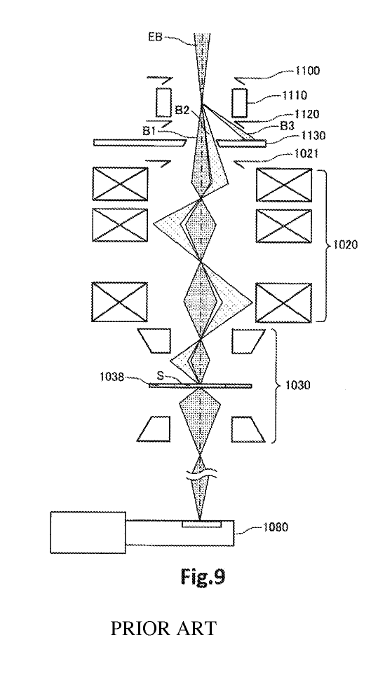

The configuration of a charged particle beam system associated with a second embodiment of the present invention is next described by referring to FIG. 6, which schematically shows main portions of the charged particle beam system, 200, associated with the second embodiment. In FIG. 6, for the sake of convenience, only members present around the beam blanker 1 are shown. Members not shown are similar to their respective counterparts of the charged particle beam system 100 shown in FIGS. 1 and 2. Those components of the charged particle beam system 200 associated with the second embodiment which are similar in function to their respective counterparts of the charged particle beam system 100 associated with the first embodiment are indicated by the same reference numerals as in the above cited figures and a description thereof is omitted.

In the above-described charged particle beam system 100, the beam blanker 1 is disposed between the charged particle beam source 110 and the condenser lens system 120 as shown in FIGS. 1 and 2. In contrast, in the charged particle beam system 200, the beam blanker 1 is disposed between the upper polepiece 142 of the objective lens 140 and the sample stage 130 as shown in FIG. 6. A crossover is formed at the principal plane of deflection of the first deflector 20a of the beam blanker 1, for example, by the condenser lens system 120. In the illustrated example, the first apertured portion 30 and second apertured portion 32 are fixed apertures. They may also be movable apertures. The charged particle beam system 200 is similar in operation to the above-described charged particle beam system 100 and a description of the operation of the system 200 is omitted.

In the charged particle beam system 200, the beam blanker 1 is disposed between the upper polepiece 142 of the objective lens 140 and the sample stage 130. Consequently, the system 200 can yield advantageous effects similar to the effects of the charged particle beam system 100.

Furthermore, in the charged particle beam system 200, the beam blanker 1 deflects the electron beam EB focused by the condenser lens system 120. Therefore, the members constituting the beam blanker 1 such as deflection plate electrodes 21, 22 and apertured portions 30, 32 can be reduced in size. This allows for miniaturization of the beam blanker 1.

In addition, in the charged particle beam system 200, the electron beam EB that has been focused by the condenser lens system 120 is deflected and so the angle of deflection of the electron beam EB in the first deflector 20a assumed during blanking can be reduced. This makes it possible to reduce the blanking voltages applied to the deflectors 20a, 20b, and 20c. Consequently, shuttering can be effected at higher speeds.

### 3. Modification

It is to be understood that the present invention is not restricted to the above embodiments but rather they can be practiced in various modified forms within the scope of the present invention. In the first and second embodiments, each of the charged particle beam systems 100 and 200 is a transmission electron microscope (TEM). The invention is also applicable to the charged particle beam systems 100 and 200 where they are equipped with a spherical aberration corrector (Cs corrector). In this case, the Cs corrector is disposed between the second condenser lens 120b and the condenser minilens 120c of the charged particle beam system 100 or 200 or between the coil 146 and the first intermediate lens 150a. No restrictions are placed on the charged particle beam system associated with the present invention as long as the system uses a beam of charged particles such as electrons or ions. The charged particle beam system associated with the present invention may be an electron microscope (such as a scanning transmission electron microscope (STEM) or a scanning electron microscope (SEM)) or a focused ion beam (FIB) system.

In the charged particle beam system associated with the present invention, the angle of incidence of the electron beam to the sample can be suppressed from varying during shuttering as described previously. Accordingly, where the charged particle beam system associated with the present invention is a scanning transmission electron microscope (STEM), for example, when dark field imaging is done using an annular dark field detector or when electron energy-loss spectroscopy (EELS) is performed using an EELS detector arranged inside the annular dark field detector, if shuttering is effected, it is possible to suppress the angle of incidence of the electron beam EB hitting the EELS detector from varying. Consequently, good EELS spectra can be obtained.

The present invention embraces configurations substantially identical (e.g., in function, method, and results or in purpose and advantageous effects) with the configurations described in the embodiments of the invention. Furthermore, the invention embraces configurations described in the embodiments and including configurations which have non-essential configurations replaced. In addition, the invention embraces configurations which produce the same advantageous effects as those produced by the configurations described in the embodiments or which can achieve the same objects as the configurations described in the embodiments. Further, the invention embraces configurations which are similar to the configurations described in the embodiments except that well-known techniques have been added.

Having thus described my invention with the detail and particularity required by the Patent Laws, what is desired protected by Letters Patent is set forth in the following claims.

The invention claimed is:

1. A charged particle beam system comprising:
a charged particle beam source for producing a charged particle beam;
a beam blanker for blanking the charged particle beam produced from the charged particle beam source; and
a sample stage for holding a sample on which the charged particle beam passed through the beam blanker impinges,
wherein the beam blanker has a multistage deflector assembly having multiple stages of deflectors for deflecting the charged particle beam and a first apertured portion disposed between first and second stages of deflectors of the multistage deflector assembly; and
wherein the charged particle beam which has passed through the first apertured portion after being deflected by the first stage of deflector is deflected back to an optical axis by the second and subsequent stages of deflectors of the multistage deflector assembly.

2. The charged particle beam system as set forth in claim 1, further comprising a condenser lens assembly for focusing said charged particle beam passed through said beam blanker onto said sample, and wherein the beam blanker is disposed between said charged particle beam source and the condenser lens assembly.

3. The charged particle beam system as set forth in claim 1, wherein said beam blanker has a lens for forming a crossover of said charged particle beam at a principal plane of deflection of the first stage of deflector.

4. The charged particle beam system as set forth in claim 1, further comprising an imaging lens system for focusing said charged particle beam transmitted through said sample.

5. The charged particle beam system as set forth in claim 1, further comprising an objective lens having an upper polepiece and a lower polepiece which are disposed on opposite sides of said sample stage, and wherein said beam blanker is disposed between the upper polepiece and the sample stage.

6. The charged particle beam system as set forth in claim 1, wherein said multistage deflector assembly produces electric fields to deflect said charged particle beam.

7. The charged particle beam system as set forth in claim 1,
wherein said multiple stages of deflectors of said multistage deflector assembly are three stages of deflectors;
wherein the angle of deflection θ1 of the charged particle beam in the first stage of deflector, the angle of deflection θ2 of the beam in the second stage of deflector, and the angle of deflection θ3 of the beam in the third stage of deflector have the relationship: |θ1|:|θ2|:|θ3|=1:2:1; and
wherein the angle of deflection θ1 and angle of deflection θ3 are opposite in sign to the angle of deflection θ2.

8. The charged particle beam system as set forth in claim 7, wherein said beam blanker further includes a second apertured portion disposed between the second stage of deflector and the third stage of deflector.

9. The charged particle beam system as set forth in claim 1, further comprising a current measuring section for measuring the amount of current of said charged particle beam impinging on said first apertured portion.

10. The charged particle beam system as set forth in claim 1, wherein said first apertured portion includes an apertured plate having a plurality of aperture openings, and wherein the apertured plate is movably mounted.

11. The charged particle beam system as set forth in claim 8, further comprising a current measuring section for measuring the amount of current of said charged particle beam impinging on said second apertured portion.
